(19) United States
(12) Patent Application Publication
(10) Pub. No.: US 2022/0196743 A1
(43) Pub. Date: Jun. 23, 2022

(54) METHOD FOR CHECKING A PROTECTION METHOD FOR PROTECTING A BATTERY DEVICE

(71) Applicant: AVL List GmbH, Graz (AT)

(72) Inventors: Mathias DEIML, Donaustauf (DE); Günther FRIZBERG, Graz (AT); Kurt GSCHWEITL, Eggersdorf (AT); Vipul DHINGRA, Graz (AT)

(73) Assignee: AVL List GmbH, Graz (AT)

(21) Appl. No.: 17/604,458

(22) PCT Filed: Apr. 16, 2020
(86) PCT No.: PCT/AT2020/060156

§ 371 Date: Oct. 18, 2021

(30) Foreign Application Priority Data
Apr. 17, 2019 (AT) A50351/2019

(51) Int. Cl. G01R 31/367; G01R 31/392; G01R 31/374; H01M 10/42; G01R 31/382; H02J 7/00

(52) U.S. Cl. CPC G01R 31/367; G01R 31/392; G01R 31/374; H02J 7/0048; G01R 31/382; H02J 7/005; H01M 10/4285

(57) ABSTRACT

The invention relates to a method for checking a protection method for protecting a battery device (100), in particular an electrode of the battery device (100), comprising the following steps: monitoring at least one electrical battery parameter (EBP) of the battery device (100); monitoring at least one operating parameter (BP) of an operating current (IB) of the battery device (100); monitoring at least one disturbance parameter (SP) of a disturbance current (IS) of the battery device (100); comparing the monitored disturbance parameter (SF), the monitored operating parameter (BP) and/or the monitored battery parameter (EBP) with at least one comparison parameter (VP) based on the battery parameter (EBP) and/or on the operating parameter (BP).

The present invention relates to a method for checking a protection method for protecting a battery device, in particular an electrode of the battery device, as well as a checking device for carrying out such a method and a corresponding computer program product.

It is known that battery devices need to be protected in order to reduce the ageing process of such a battery device. With known battery devices, ageing processes occur which cause the battery to age in terms of its capacity. These ageing processes are based on chemical and physical principles. One problem with regard to the ageing of battery devices arises from the build-up of layers on the respective electrode of the battery device. During operation of the battery device, Le. when charging and discharging or when storing and delivering electrical energy, transitions of electrons or ions take place at the respective electrode. During these transitions it can happen that the transition is only partially successful and in this way material is deposited on an electrode. If this material deposit builds up, a layer is created on the electrode which has an insulating effect on the transition of electrons or ions. The more extensive this layer is or the thicker this layer is formed, the lower the capacity of the battery device and, accordingly, the poorer its state of health or ageing condition.

The aim of known solutions for limiting the ageing of battery devices is to actively influence the temperature of the battery device. Since the temperature has an effect on the chemical and physical processes responsible for the ageing condition of the battery, with the known solutions controlling the temperature can provide a way of protecting the battery device from ageing too quickly. However, a disadvantage of the use of temperature control is that this reduces the usability of the battery device, in particular during the exercise of the temperature checking function. In addition, a relatively high energy requirement is necessary for temperature control in order for example to heat up a cold battery device or to cool down an excessively warm battery device,

It is therefore the object of the present invention to remedy, at least in part, the disadvantages described above. In particular, it is the object of the present invention to check a protection method for protecting a battery device, in particular an electrode of a battery device, in a cost-effective and simple manner.

According to the invention, this is achieved by a method for checking a protection method for protecting a battery device, in particular an electrode of the battery device. Such a method comprises the following steps:
monitoring at least one electrical battery parameter of the battery device,
monitoring at least one battery parameter of an operating current of the battery device,
monitoring at least one disturbance parameter of a disturbance current of the battery device,
comparing the monitored disturbance parameter, the monitored operating parameter and/or the monitored battery parameter with at least one comparison parameter based on the battery parameter and/or the operating parameter.

The above object is achieved by a method with the features of claim 1, a checking device with the features of claim 12 and a computer program product with the features of claim 14. Further features and details of the invention arise from the dependent claims, the description and the drawings. Naturally, features and details which are described in connection with the method according to the invention also apply in connection with the checking device according to the invention as well as the computer program product according to the invention and vice versa, so that with regard to the disclosure, mutual reference is or can always be made to the individual aspects of the invention.

A method according to the invention is based on the assumption that a protection method for protecting the battery device, in particular the electrode or another component of the battery device is implemented. Such a protection method is in particular a protection method which uses a disturbance current. A disturbance current is to be understood according to the present invention as a current which is applied to the battery device separately from the operating current of the battery device. For example, in a charging state of the battery device an operating current is provided by the charging current. Corresponding operating parameters of such an operating current are the current frequency and the current amplitude of such a charging current. In such a case the electrical battery parameter is for example the basic charging state of the battery device or, directly, the ageing condition, also called the state of health (SOH). Further electrical battery parameters can also be provided by the state of charge (SOC) of the battery device.

In a protection method according to the present invention, this operating current is superimposed with a disturbance current which has at least one defined disturbance parameter. According to the invention, the disturbance current is preferably different from the operating current, in particular with regard to at least one current parameter. Such a current parameter preferably forms the respective disturbance parameter. In particular, such disturbance parameters are also the current amplitude and/or the current frequency of the disturbance current.

According to the invention, it is thereby irrelevant whether the disturbance current is actively applied in a targeted manner or recognised as an existing disturbance current in the circuit of the battery device and thus consciously tolerated according to the invention. However, it is preferable if an active protection method is used which determines corresponding disturbance parameters based on the battery parameter and the operating parameter of a battery current and generates disturbance currents and applies these to the operating current.

According to the invention, such a protection method is not only carried out in a controlled manner, but is in addition also monitored using a method according to the invention. This monitoring is achieved through a comparison with at least one comparison parameter. Preferably, the comparison parameter is thereby based, directly or indirectly, on the battery parameter and/or the operating parameter. For example, it is conceivable that the comparison parameter is formed directly by the operating parameter or the battery parameter. However, the comparison parameter can also reflect the battery parameter and/or the operating parameter indirectly or even form a combination thereof.

Thus, according to the invention the last step of the method offers a feedback which makes it possible to monitor the protection method for protecting an electrode in a controlled way. This primarily serves to compare the monitored disturbance parameter, the monitored operating parameter or the monitored battery parameter with the comparison parameter with regard to quantity or quality and thus to monitor these. hi the simplest case, this allows a direct checking and thus a quality assurance of the protection method. In this way, it is possible to fundamentally monitor, qualitatively, that the protective function is provided, in the right direction as well as with the correctly formed disturbance current quality and quantity. However, in addition, quantitative monitoring is also possible, so that the quantity of the protective effect can not only be monitored, but, as will be explained later, also improved for subsequent disturbance currents.

In other words, a disturbance process can now be monitored in a direct or indirect manner and improved over the service life of the battery device or even used in an improved way to achieve an increased operating life of the battery device.

It is advantageous if, in a method according to the invention, the comparison is carried out on the basis of a simulation model of the battery device which takes into account in particular at least one of the following parameters:
ageing condition of the battery device
state of charge of the battery device
temperature of the battery device
quality and/or quantity of the disturbance parameter
quality and/or quantity of the operating parameter
quality and/or quantity of the battery parameter

The above list is not intended to be definitive. The individual data can be made available for example by a test bench, and thus incorporated once in the corresponding simulation model. However, it is also conceivable that the simulation model has a so-called artificial intelligence or a neural network going beyond a purely numerical reproduction of data. This allows use in a vehicle as well as in other stationary applications of the battery device.

It is also advantageous if, in a method according to the invention, a comparison of a battery parameter and/or an operating parameter with a comparison parameter is carried out after an application of a disturbance current has been finished. While in principle a method according to the invention can naturally be carried out continuously, semi-continuously or in steps on a regular basis, a decisive advantage can be achieved if the result of this disturbance current can be evaluated through the comparison parameter, in particular following the application of a disturbance current. The comparison parameter preferably relates to a situation before application or to a situation without application of the disturbance current. In other words, the battery parameter, in particular for example the ageing condition of the battery device, or the operating parameter, for example the operating current of the battery device, is checked following application of the disturbance current and is compared with a comparison parameter for the operating parameter or the battery parameter. For example, it is conceivable that the ageing condition, as battery parameter, is compared with a corresponding comparison parameter following application of the disturbance current. In such a case, the comparison parameter likewise reflects the ageing condition, so that a difference between the ageing condition according to the comparison parameter and the determined ageing condition according to the battery parameter can be determined following application of the disturbance current. This difference can indicate whether and in what qualitative manner the disturbance current has achieved the desired effect.

In a method according to the preceding paragraph it is possible that the comparison parameter comprises a battery parameter and/or an operating parameter before and/or during application of the disturbance current. In this way it is possible to make the comparison explained in the previous paragraph even more specific. Thus, ideally, the battery parameter following application of the disturbance current for example can reflect the ageing condition following the disturbance current and can now be compared with a comparison parameter in the form of an ageing condition before application of the disturbance current. In this way, the ageing and thus the difference between these two ageing conditions before the disturbance current and following the disturbance current can be compared with one another. This makes it possible to determine the reduction in the capacity of the battery device over the course of the application of the disturbance current. In particular, this provides an indication of how slowly or how rapidly the ageing happens during the application of the disturbance current. In addition to a comparison simply carried out before and following application of the disturbance current, such a comparison is naturally also conceivable during the application of the disturbance current, so that the check not only offers a final checking function following a protective mechanism, but also offers a checking function while such a protective mechanism is being applied.

It can also be advantageous if, in a method according to the preceding paragraph, the result of the comparison is taken into account for a subsequent application of a disturbance current. If an evaluation is possible which evaluates an application of a disturbance current in a battery device with regard to its quality, then this success evaluation can be used to create or allow a modified disturbance current in a subsequent application. In other words, not only can a quality monitoring according to the invention be provided but, in addition, also a feedback improving the quality during the course of the protection method according to the invention. This feedback can be provided both within individual battery devices or also across a plurality of battery devices. Thus, this success evaluation can for example be fed back to and stored in a higher-level data cloud in order to provide the corresponding feedback to other battery devices at other locations. Naturally, it is also possible to provide a feedback into the simulation model of the battery device already explained in order to further improve the quality of the simulation model during ongoing operation of a method according to the invention.

It is further advantageous if, in a method according to the invention, an ageing condition of the battery device following the disturbance current is used as battery parameter with a comparison parameter in the form of an ageing parameter of the battery device before the disturbance current and/or during the disturbance current. Thus, ageing conditions become explicitly comparable with one another, so that the rate of ageing over the course of the disturbance current can be recognised. In particular, a reduced ageing can be detected in this way, and thus a success monitoring of the disturbance current can be carried out. As has already been explained several times, this can be followed by both a feedback into disturbance currents applied in future and a feedback into an ageing model in the form of a simulation model of the battery device.

It is further advantageous if, in a method according to the invention, an ageing gradient is determined during the comparison of these ageing conditions. Thus, the gradient of the ageing conditions or the decrease in the ageing condition can be determined, so that the speed of the ageing can be used as a quality characteristic for the success of the disturbance current. This makes it possible to integrate the quality into a highly compact single comparison parameter or success parameter and to make this available for further evaluations.

Further advantages can be achieved if, in a method according to the invention, the result of the comparison is used for an in particular subsequent generation of the disturbance parameter. Such a feedback involves a feedback into the disturbance check which, with active generation of the disturbance parameter and active generation of the disturbance current, makes it possible to adapt this, for future disturbance current situations, to the findings from the past disturbance current situation. This feedback thus allows not only a regulation within the disturbance current itself, but also, so to speak, a continuous self-learning system for the future application of the protection method for the electrode.

In addition, it is advantageous if, in a method according to the invention, a comparison parameter from at least one external battery device is used for the comparison. As has already been explained, it can be possible to save the results of the comparisons to a cloud and thus make these available to other battery devices. If the battery devices are for example used in stationary applications in a wide variety of geographical situations, or if they are mobile in different vehicles, then in this way a method according to the invention can provide a communication between the checking devices of these battery devices. However, complete monitoring data no longer needs to be exchanged between the battery devices, only the results of the comparison or the comparison parameters themselves. In this way, ageing conditions, success results of individual disturbance currents, but also the use of disturbance parameters and specific disturbance currents can be exchanged between different battery devices simply, cost-effectively and above all using very little data.

It can also be advantageous if, in a method according to the invention, a battery parameter and/or an operating parameter without application of a disturbance current is used as comparison parameter. Such information is for example obtained from a corresponding simulation model or through comparison with a battery device running on a parallel test bench. A test bench model on which, as a simulation model, a later use of the battery device can be based is also in principle conceivable here. In other words, the real situation on application of the disturbance current can now be compared, during application of the disturbance current and/or following application of the disturbance current, with a situation without such a disturbance current. This makes it possible to carry out a comparison at least with an imaginary non-protected battery device, and in this way, at least in imaginary form, to prove and record the extended ageing situation or the extended usage situation of the battery device.

It can bring further advantages if, in a method according to the invention, a simulation model of the battery device is used for the comparison parameter. Such a simulation model can likewise be made available from a simulation in the vehicle, from a simulation in the battery device, but also from a simulation on a test bench. In such a case, real comparison values are no longer necessary, so that the corresponding measuring effort, in particular the need for sensor devices, can be reduced. As has already been explained several times, such a simulation model can be designed to be capable of learning through the corresponding feedback during success checking, so that it improves over the period of use of a method according to the invention and thus the overall process is also optimised with regard to its inventive quality.

The subject matter of the present invention also includes a checking device for checking a battery device. Such a checking device has a monitoring module for monitoring at least one electrical battery parameter of a battery device, monitoring at least one operating parameter of an operating current of the battery device and monitoring at least one disturbance parameter of a disturbance current of the battery device. Furthermore, a comparison module is provided for comparing the monitored disturbance parameter, the monitored operating parameter and/or the monitored battery parameter with at least one comparison parameter based on the battery parameter and/or based on the operating parameter. The monitoring module and/or the comparison module are preferably designed for the implementation of a method according to the invention. Thus, a checking device according to the invention brings the same advantages as have been explained in detail with reference to a method according to the invention.

The subject matter of the present invention also includes a computer program product comprising commands which, when the program is run on a computer, cause this to carry out the method according to the present invention. Thus, a computer program product according to the invention brings the same advantages as have been explained in detail with reference to a method according to the invention.

Further advantages, features and details of the invention are explained in the following description, in which exemplary embodiments of the invention are described in detail with reference to the drawings. In each case schematically:

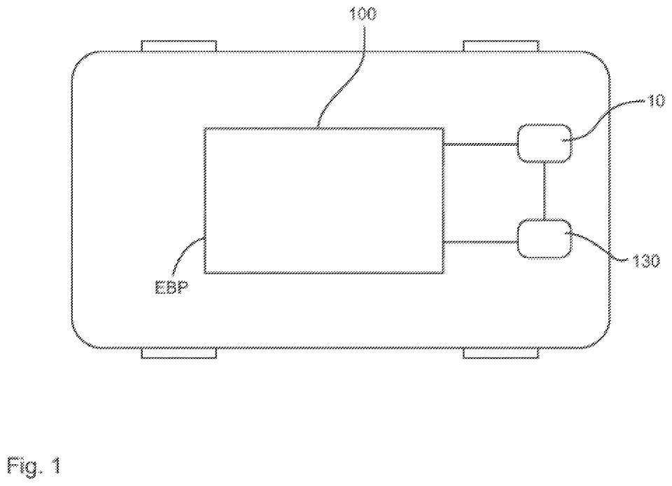

FIG. 1 shows an embodiment of a checking device according to the invention

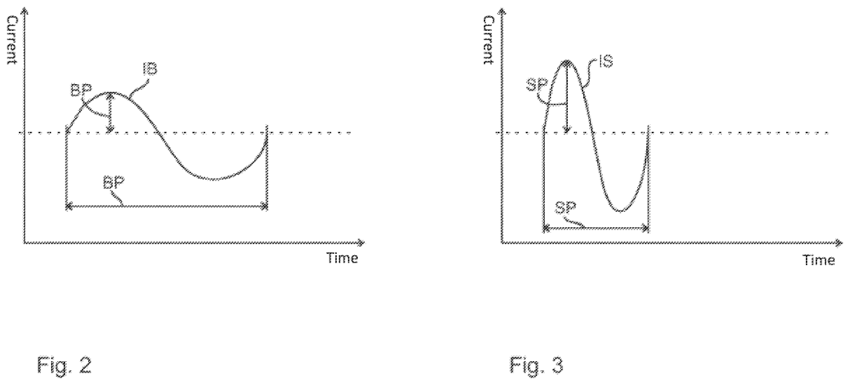

FIG. 2 shows a situation with an operating current,

FIG. 3 shows a situation with a disturbance current,

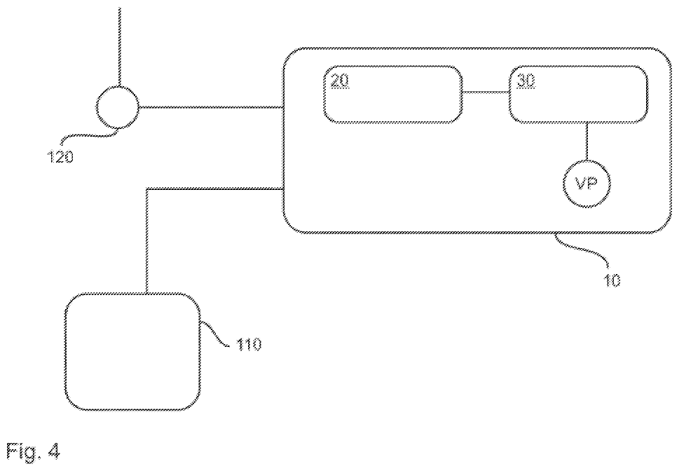

FIG. 4 shows an embodiment of a checking device according to the invention,

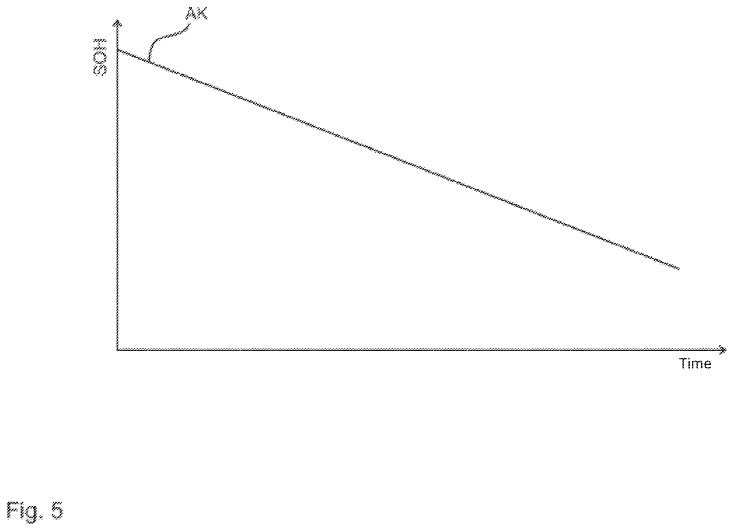

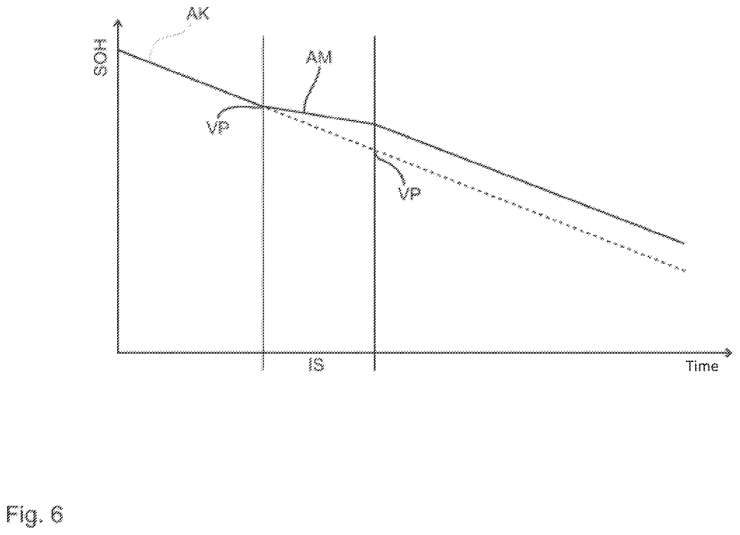

FIG. 5 shows an ageing condition gradient without disturbance current,

FIG. 6 shows an ageing condition with a first disturbance current and

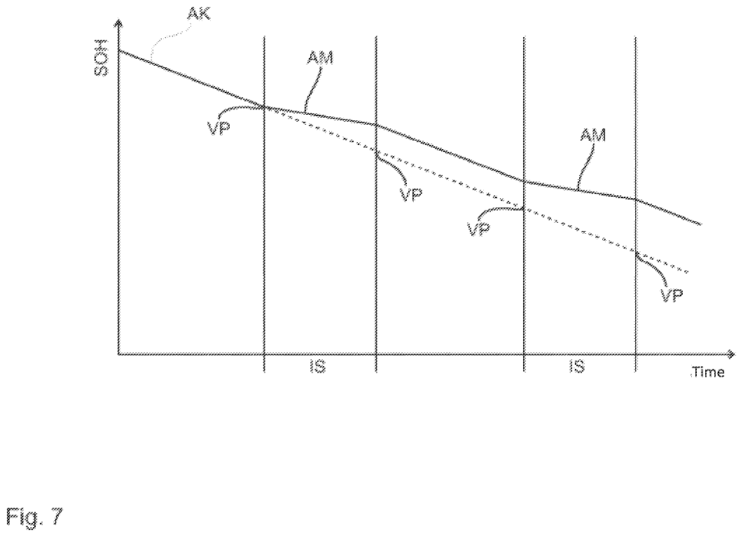

FIG. 7 shows an ageing condition with two disturbance currents.

A mobile battery device 100 in a vehicle is shown schematically in FIG. 1. In this case this is provided with a checking device 10 on which a method according to the invention is running. Based for example on the electrical battery parameter EBP and on a corresponding operating parameter BP, it is possible to generate a disturbance current IS which is superimposed on an operating current 1B. This disturbance current IS can for example be generated by a secondary component 130, for example in the form of an inverter for the battery device 100 within the circuit of same.

The function of such a disturbance current IS will be explained briefly with reference to FIGS. 2 and 3. A normal operating current IB is for example shown according to FIG. 2. With a defined frequency and a defined amplitude, two operating parameters BP of the operating current IB are shown here. On this basis, a disturbance current IS can now be determined according to FIG. 3, whereby in this case an increased amplitude and a shortened frequency in comparison with the operating current IB have been generated as disturbance parameter SP. As explained with reference to FIG. 1, the disturbance current IS can for example be generated by a secondary component 130. This disturbance current IS, which can also be described as ripple current, is now applied to the operating current 1B and so to speak superimposed on this. In this way it becomes possible to protect the respective electrode of the battery device 100 in a chemical and/or physical manner, since a disharmonious transition at the respective electrode inhibits or even completely prevents the build-up of a layer on the respective electrode. This effect is maintained as long as the disturbance current IS is superimposed on the operating current IB.

FIG. 4 shows, schematically, a checking device 10 according to the present invention which makes it possible to carry out the check with the aid of a monitoring module 20 and a comparison module 30. For example, a sensor device 120, but also a simulation model 110 can serve to input data.

The way a protection method according to the invention works is clearly illustrated in FIGS. 5 to 7 in particular. FIG. 5 shows, schematically, in linear representation, an ageing gradient of a battery device 100 in the form an ageing curve AK. The state of health SOH is plotted in the y-direction above the time on the x-axis, In normal operational use of the battery device 100, the state of health SOH decreases in line with the ageing curve AK. In reality, this will only very rarely be a linear correlation, but will usually be a non-linear correlation. According to the invention, a monitoring for the purpose of reducing this rate of ageing is now possible. As has already been explained, a disturbance current IS can be used for the reduction. A corresponding example is shown in FIG. 6. In a time window, a disturbance current IS is now applied which, through its physical and/or chemical protective effect, slows down the rate of ageing of the respective electrode of the battery device 100. While the ageing continues to take place, i.e. the ageing curve AK and thus the state of health SOH also declines during application of the disturbance current IS, it does so more slowly. Various comparison parameters VP can be used in order to determine the quality and/or the quantity of the success of this disturbance current IS and thus to ensure monitoring. In particular, following application of the disturbance current IS, a comparison is carried out either with a comparison parameter VP before application of the disturbance current IS or with a comparison [parameter] without application of the disturbance current IS. The corresponding information can for example be provided by sensor devices 120 and/or simulation models 110. In addition, the change gradient AM is also shown in FIG. 6 which can be used as comparison parameter VP, but also as battery parameter ESP.

In addition to simple checking, as shown in FIG. 6, a feedback for subsequent disturbance currents IS is also possible, as shown in FIG. 7. Thus, a feedback for the second disturbance current IS can be derived from the success of the first disturbance current IS which, in an improved manner, slows down even further the ageing gradient AM for example. Naturally, a feedback into the simulation model 110 is also conceivable within the scope of the present invention,

The above explanation of the embodiments describes the present invention exclusively in the context of examples. Naturally, individual features of the embodiments can, where technically expedient, be freely combined with one another without departing from the scope of the present invention.

### REFERENCE SIGNS

10 checking device
20 monitoring module
30 comparison module
100 battery device
110 simulation model
120 sensor device
130 secondary component
EBP battery parameter
BP operating parameter
IB operating current
SP disturbance parameter
IS disturbance current
VP comparison parameter
AK ageing curve
AM ageing gradient
SOH state of health

1. Method for checking a protection method for protecting a battery device (100), in particular an electrode of the battery device (100), comprising the following steps:
monitoring at least one electrical battery parameter (EBP) of the battery device (100),
monitoring at least one operating parameter (BP) of an operating current (IB) of the battery device (100),
monitoring at least one disturbance parameter (SP) of a disturbance current (IS) of the battery device (100),
comparing the monitored disturbance parameter (SP), the monitored operating parameter (BP) and/or the monitored battery parameter (EBP) with at least one comparison parameter (VP) based on the battery parameter (EBP) and/or the operating parameter (BP).

2. Method according to claim 1, characterised in that the comparison is carried out on the basis of a simulation model (110) of the battery device (100) which in particular takes into account at least one of the following parameters:
ageing condition of the battery device (100)
state of charge of the battery device (100)
temperature of the battery device (100)
quality and/or quantity of the disturbance parameter (SP)
quality and/or quantity of the operating parameter (BP)
quality and/or quantity of the battery parameter (EBP).

3. Method according to claim 1, characterised in that a comparison of a battery parameter (EBP) and/or of an operating parameter (EBP) with a comparison parameter (VP) is carried out after an application of a disturbance current (IS) has been finished.

4. Method according to claim 3, characterised in that the comparison parameter (VP) comprises a battery parameter (EBP) and/or an operating parameter (BP) before and/or during application of the disturbance current (IS).

5. Method according to claim 4, characterised in that the result of the comparison is taken into account for a subsequent application of a disturbance current (IS).

6. Method according to claim 3, characterised in that an ageing condition of the battery device (BP) following the disturbance current (IS) is used as battery parameter (EBP) with a comparison parameter (VP) in the form of an ageing condition of the battery device (100) before the disturbance current (IS) and/or during the disturbance current (IS).

7. Method according to claim 6, characterised in that an ageing gradient (AM) is determined during the comparison of the ageing conditions.

8. Method according to claim 1, characterised in that the result of the comparison is used for an in particular subsequent generation of the disturbance parameter (SP).

9. Method according to claim 1, characterised in that a comparison parameter (VP) from at least one external battery device (100) is used for the comparison.

10. Method according to claim 1, characterised in that a battery parameter (EBP) and/or an operating parameter (BP) without application of a disturbance current (IS) is used as comparison parameter (VP).

11. Method according to claim 10, characterised in that a simulation model (110) of the battery device (100) is used for the comparison parameter (VP).

12. Checking device (10) for checking a battery device (100), comprising a monitoring module (20) for monitoring at least one electrical battery parameter (EBP) of a battery device (100), monitoring at least one operating parameter (BP) of an operating current (IB) of the battery device (100) and monitoring at least one disturbance parameter (SP) of a disturbance current (IS) of the battery device (100), further comprising a comparison module (30) for comparing the monitored disturbance parameter (SP), the monitored operating parameter (BP) and/or the monitored battery parameter (EBP) with at least one comparison parameter (VP) based on the battery parameter (EBP) and/or the operating parameter (BP).

13. Checking device (10) according to claim 12, characterised in that the monitoring module (20) and/or the comparison module (30) are designed for the implementation of a method comprising the following steps:
monitoring at least one electrical battery parameter (EBP) of the battery device (100),
monitoring at least one operating parameter (BP) of an operating current (IB) of the battery device (100),
monitoring at least one disturbance parameter (SP) of a disturbance current (IS) of the battery device (100),
comparing the monitored disturbance parameter (SP), the monitored operating parameter (BP) and/or the monitored battery parameter (EBP) with at least one comparison parameter (VP) based on the battery parameter (EBP) and/or the operating parameter (BP).

14. Computer program product comprising commands which, when the program is run on a computer, cause this to carry out the method with the features of claim 1.
